(19) United States
(12) Patent Application Publication
(10) Pub. No.: US 2018/0199460 A1
(43) Pub. Date: Jul. 12, 2018

(54) ARRAY OF GRAPHITE OVER FOAM HAVING MULTI-CROSS SECTION TO INCREASE HEAT TRANSFER ABILITY IN AN ELECTRONIC DEVICE

(71) Applicant: XIAONING WU, BEIJING (CN)

(72) Inventor: XIAONING WU, BEIJING (CN)

(73) Assignee: JONES TECH INC., SUNNYVALE, CA (US)

(21) Appl. No.: 15/400,990

(22) Filed: Jan. 7, 2017

(51) Int. Cl. H05K 7/20; F28F 13/00; F28F 21/02

(52) U.S. Cl. CPC H05K 7/2039; F28F 2275/025; F28F 21/02; F28F 13/003

(57) ABSTRACT

Disclosed is a graphite-over-foam structure for increasing heat conductivity between the heat spreader and the heat source. The graphite-over-foam structure includes a first foam core unit, a first graphite layer, a second foam core unit, a second graphite layer and a first bonding adhesive. The first foam core unit is configured to fill the air gap between the heat spreader and the heat source. The first graphite layer is wrapped around the first foam to do heat-conducting function between the heat source and the heat spreader. The second foam core unit is positioned next to the first foam core unit to fill the air gap between the heat spreader and the heat source. The second graphite layer is wrapped around the second foam core unit and bonded with the first graphite layer to create a first cross-section to expand the heat conducting paths. The first bonding adhesive positioned between the first graphite layer and the second graphite layer to create a bonding of the first foam core unit and the second foam core unit into a single foam core unit. The first bonding adhesive attaches the first graphite layer and the second graphite layer to the heat source of the electronic device. The first graphite layer and the second graphite layer are smaller in structure and have a first cross-section that increases the graphite path of heat conducting between heat spreader and the heat source of the electronic device.

### BACKGROUND OF THE INVENTION

### 1. Field of the Invention

The present invention generally relates to graphite over foam structure, and more particularly relates to an array of graphite over foam having multi-cross section to increase heat transfer ability between heat emitting components of an electronic device.

### 2. Description of Related Art

In recent years, electronic devices have become smaller and more densely packed. Designers and manufacturers are now facing the challenge of dissipating the heat generated in these devices using various thermal management systems. Thermal management has evolved to address the increased temperatures created within such electronic devices as a result of the increased processing speed and power of these devices.

The portable computing devices become more advanced, higher processing demands required to deliver advanced features produce increasingly greater amounts of heat. When the portable computing devices do not include active cooling devices, such as for example fans, heat can become trapped in isolated areas of the device in which the heat is generated.

The new generation of electronic components squeezes more power into a smaller space; and hence the relative importance of thermal management within the overall product design continues to increase. Various heat spreaders or thermal pads are available for spreading heat across a surface of a subassembly.

However, these heat spreader or thermal pad are most efficient at transferring heat in plane and thus having a limited thermal conductivity for bridging a gap between separated subassemblies of a device. The heat is conducted along the skin of graphite and thus with one cross-section, the total thermal conductivity is lower than 1 w/m-k.

Therefore, there is a need of an array of graphite over foam having multi-cross section to increase heat transfer ability between heat emitting components of an electronic device. Further, the array of graphite over foam should be able to close the gaps to improve heat conducting between the heat spreader and the heat source of the electronic device.

### SUMMARY OF THE INVENTION

In accordance with teachings of the present invention, a graphite-over-foam structure for increasing heat conductivity between heat spreader and heat source of an electronic device is provided.

An object of the present invention is to provide a graphite-over-foam structure for increasing heat conductivity. The graphite-over-foam structure includes a first foam core unit, a first graphite layer, a second foam core unit, a second graphite layer and a first bonding adhesive.

The first foam core unit is configured to fill the air gap between the heat spreader and the heat source. The first graphite layer is wrapped around the first foam to do heat-conducting function between the heat source and the heat spreader. The second foam core unit is positioned next to the first foam core unit to fill the air gap between the heat spreader and the heat source.

The second graphite layer is wrapped around the second foam core unit and bonded with the first graphite layer to create a first cross-section to expand the heat conducting paths. The first bonding adhesive positioned between the first graphite layer and the second graphite layer to create a bonding of the first foam core unit and the second foam core unit into a single foam core unit.

The first bonding adhesive attaches the first graphite layer and the second graphite layer to the heat source of the electronic device. The first graphite layer and the second graphite layer are smaller in structure and have a first cross-section that increases the graphite path of heat conducting between heat spreader and the heat source of the electronic device.

Another object of the present invention is to provide the graphite-over-foam structure with a third foam core unit, a third graphite layer and a second bonding adhesive. The third foam core unit positioned next to the second foam core unit to fill the air gap between the heat spreader and the heat source. The third graphite layer wrapped around the third foam core unit and bonded with the second graphite layer to create a second cross-section to expand the heat conducting paths.

The second bonding adhesive positioned between the second graphite layer and the third graphite layer to create a bonding of the second foam core unit and the third foam core unit into the single foam core unit. The second bonding adhesive attaches the second graphite layer and the third graphite layer to the heat source of the electronic device.

Another object of the present invention is to provide the graphite-over-foam structure wherein plurality of foam core unit clad by the graphite layer are bonded together to create plurality of cross-section to expand more heat conducting paths for increasing heat conductivity between the heat source and the heat sink.

### BRIEF DESCRIPTION OF DRAWINGS

FIG. 1 illustrates a schematic diagram to illustrate a graphite-over-foam structure positioned in between heat spreader and heat source of an electronic device; and

FIG. 2 illustrates a perspective view of the graphite-over-foam structure in accordance with a preferred embodiment of the present invention.

### DETAILED DESCRIPTION OF DRAWINGS

While this technology is illustrated and described in a preferred embodiment a graphite-over-foam structure positioned in between heat spreader and heat source of an electronic device may be produced in many different configurations, shapes, sizes, forms and materials. There is depicted in the drawings, and will herein be described in detail, as a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the technology described herein.

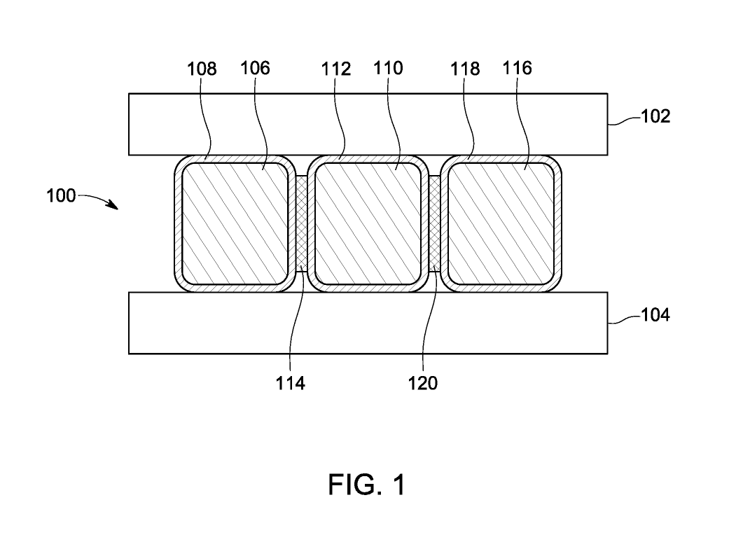

FIG. 1 illustrates a schematic diagram to illustrate a graphite-over-foam structure 100 positioned in between heat spreader 102 and heat source 104 of an electronic device. In accordance with a preferred embodiment of the present invention, the graphite-over-foam structure 100 includes a first foam core unit 106, a first graphite layer 108, a second foam core unit 110, a second graphite layer 112 and a first bonding adhesive 114.

The first foam core unit 106 is configured to fill the air gap between the heat spreader 102 and the heat source 104. The first graphite layer 108 is wrapped around the first foam core unit 106 to do heat-conducting function between the heat source 104 and the heat spreader 102.

The second foam core unit 110 is positioned next to the first foam core unit 106 to fill the air gap between the heat spreader 102 and the heat source 104. The second graphite layer 112 is wrapped around the second foam core unit 110 and bonded with the first graphite layer 108 to create a first cross-section to expand the heat conducting paths.

The first bonding adhesive 114 is positioned between the first graphite layer 108 and the second graphite layer 112 to create a bonding of the first foam core unit 106 and the second foam core unit 110 into a single foam core unit. The first bonding adhesive 114 attaches the first graphite layer 108 and the second graphite layer 112 to the heat source 104 of the electronic device.

In another preferred embodiment of the present invention, the graphite-over-foam structure 100 includes a third foam core unit 116, a third graphite layer 118 and a second bonding adhesive 120. The third foam core unit 116 is positioned next to the second foam core unit 110 to fill the air gap between the heat spreader 102 and the heat source 104.

The third graphite layer 118 is wrapped around the third foam core unit 116 and is bonded with the second graphite layer 110 to create a second cross-section to expand the heat conducting paths. The second bonding adhesive 120 is positioned between the second graphite layer 112 and the third graphite layer 118 to create a bonding of the second foam core unit 110 and the third foam core unit 116 into the single foam core unit.

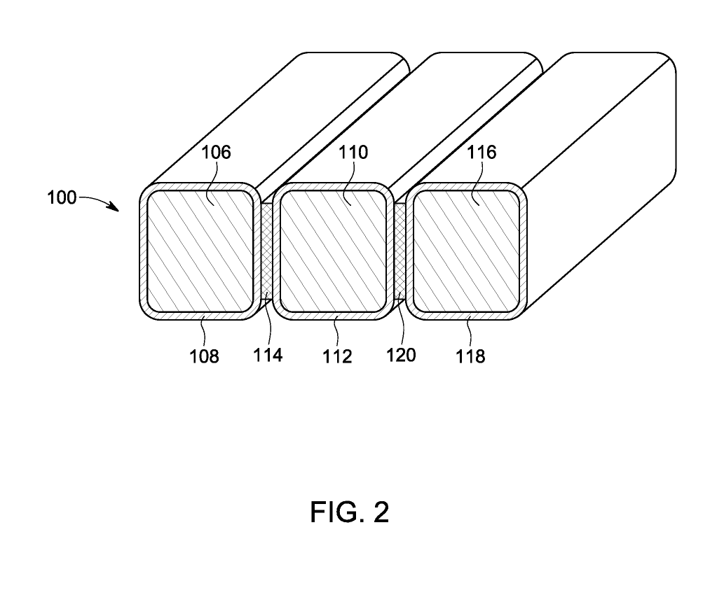

The second bonding adhesive 120 attaches the second graphite layer 112 and the third graphite layer 118 to the heat source 104 of the electronic device. The first, second and third foam core unit 106, 110, and 116; the first, second and third graphite layer 108, 112 and 118; the first and second bonding adhesive 114 and 120 is explained in detail in conjunction with FIG. 2 of the present invention.

It would be readily apparent to those skilled in the art that ‘n’ number of the foam core unit clad with the graphite layer may be bonded together to create multiple cross-section thus increasing multiple path of heat conducting between the heat spreader 102 and the heat source 104.

The graphite-over-foam 100 is filled into the gap to effectively improve heat conducting between the heat spreader 102 and the heat source 104. The graphite-over-foam 100 is having high thermal conductivity due to multiple cross-sections and further the graphite-over-foam 100 is easily compressible.

FIG. 2 illustrates a perspective view of the graphite-over-foam structure 100 in accordance with a preferred embodiment of the present invention. Examples of the material of the first foam core unit 106, the second foam core unit 110, and the third foam core unit 116 includes but not limited to urethane foam; and silicone foam.

Examples of the material of the first graphite layer 108, the second graphite layer 112, and the third graphite layer 118 includes but not limited to synthetic graphite; a nature graphite film; and a graphene-based coating film. Examples of the material of the first bonding adhesive 114 and second bonding adhesive 120 includes but not limited to pressure sensitive adhesive; epoxy adhesive; and hot-melt adhesive.

Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

1. A graphite-over-foam structure for increasing heat conductivity between heat spreader and heat source of an electronic device, the graphite-over-foam structure comprising:
a first foam core unit configured to fill the air gap between the heat spreader and the heat source;
a first graphite layer wrapped around the first foam core unit to do heat-conducting function between the heat source and the heat spreader;
a second foam core unit positioned next to the first foam core unit to fill the air gap between the heat spreader and the heat source;
a second graphite layer wrapped around the second foam core unit and bonded with the first graphite layer to create a first cross-section to expand the heat conducting paths; and
a first bonding adhesive positioned between the first graphite layer and the second graphite layer to create a bonding of the first foam core unit and the second foam core unit into a single foam core unit, wherein the first bonding adhesive to attach the first graphite layer and the second graphite layer to the heat source of the electronic device.

2. The graphite-over-foam structure according to claim 1 further comprising:
a third foam core unit positioned next to the second foam core unit to fill the air gap between the heat spreader and the heat source;
a third graphite layer wrapped around the third foam core unit and bonded with the second graphite layer to create a second cross-section to expand the heat conducting paths; and
a second bonding adhesive positioned between the second graphite layer and the third graphite layer to create a bonding of the second foam core unit and the third foam core unit into the single foam core unit, wherein the second bonding adhesive to attach the second graphite layer and the third graphite layer to the heat source of the electronic device.

3. The graphite-over-foam structure according to claim 1 wherein the first foam core unit, the second foam core unit, and the third foam core unit comprising of at least one of urethane foam; and silicone foam.

4. The graphite-over-foam structure according to claim 1 wherein the first graphite layer, the second graphite layer, and the third graphite layer comprising of at least one of synthetic graphite; a nature graphite film; and a graphene-based coating film.

5. The graphite-over-foam structure according to claim 1 wherein the first bonding adhesive and second bonding adhesive comprising of at least one of pressure sensitive adhesive; epoxy adhesive; and hot-melt adhesive.
